(19) United States
(12) Patent Application Publication
(10) Pub. No.: US 2002/0063269 A1
(43) Pub. Date: May 30, 2002

(54) Graded-dielectric structures for phase-shifting high speed signals within microstrip structures

(76) Inventor: Joseph T. DiBene II, Oceanside, CA (US)

Correspondence Address: GATES & COOPER LLP, HOWARD HUGHES CENTER, 6701 CENTER DRIVE WEST, SUITE 1050, LOS ANGELES, CA, 90045, US

(21) Appl. No.: 09/982,333

(22) Filed: Oct. 18, 2001

Related U.S. Application Data
(60) Provisional application No. 60/242,003, filed on Oct. 19, 2000.

(51) Int. Cl. H01L 29/80; H01L 23/48; H01L 29/40

(52) U.S. Cl. 257/275; 257/700; 257/758

(57) ABSTRACT

A method, apparatus, article of manufacture, and a memory structure for selectively phase shifting one or more frequency components of a signal is described. The apparatus comprises a conductor, a ground plane, a dielectric disposed between the ground plane and the conductor, wherein the dielectric is characterized by a non-homogeneous dielectric constant.

### CROSS-REFERENCE TO RELATED APPLICATIONS

This application claims benefit of U.S. Provisional Patent Application No. 60/242,003, entitled “GRADED-DIELECTRIC STRUCTURES FOR PHASE-SHIFTING HIGH SPEED SIGNALS WITHIN MICROSTRIP STRUCTURES,” by Joseph T. DiBene II, filed Oct. 19, 2000.

### BACKGROUND OF THE INVENTION

1. Field of the Invention

This invention relates to dielectric structures for selectively phase-shifting the frequency components of a signal along the path of a microstrip transmission line used within a printed circuit board (PCB) in order to mitigate the effects of dispersion as the signal propagates down the transmission path.

2. Description of the Related Art

Very high-speed digital and analog signals which are transmitted across microstrip structures, whether in PCBs or in IC packages begin to exhibit dispersion as the signals approach very high frequencies. In addition to dispersion, attenuation of the signals is also present as well as other distortion effects due to parasitics within and around the transmission paths. To combat the effects of dispersion, a mechanism is described herein which illustrates a method for phase shifting the frequency components of the signal as the signals propagate down the transmission paths in a manner so as to maintain the spatial alignment of all the frequency components.

### SUMMARY OF THE INVENTION

To address the requirements described above, the present invention discloses a method, apparatus and article of manufacture for selectively phase shifting one or more frequency components of a signal. The apparatus comprises a conductor, a ground plane, a dielectric disposed between the ground plane and the conductor, wherein the dielectric is characterized by a non-homogeneous dielectric constant. The method comprises the steps of disposing a first dielectric having a dielectric constant ε₁ on a ground plane, disposing a second dielectric having a second dielectric constant ε₂ lower than the first dielectric constant ε₁ on the first dielectric, and disposing a third dielectric having a third dielectric constant ε₃ lower than the second dielectric constant ε2, wherein the first dielectric has a first void, the second dielectric has a second void smaller than the first void and disposed over the first void.

The present invention provides a structure for a microstrip transmission line that compensates for the dispersive characteristics of such lines. This dispersive effect causes the higher frequency components of the transmitted wave to arrive later than the lower frequency components resulting in signal distortion at the receiving end of the line. By re-aligning or phase shifting the high frequency components of the transmitted signal the original shape of the pulse may be somewhat restored and pulse-width increased thus resulting in better signal fidelity.

The method described herein phase-shifts the components by grading the dielectric structure of the microstrip. As the signal propagates down the transmission path, the higher frequency components of the wave have fields that tend to focus charge density closer to the microstrip and the ground beneath it. By grading the dielectric in a fashion where the dielectric constant gets lower as one gets nearer to the microstrip the high frequency components begin to move at a greater velocity than in the outer dielectric region. This has the effect of compensating for the increase in the effective dielectric constant shift in a normal microstrip that tends to increase the effective dielectric constant as the signal frequencies or harmonics increase.

### BRIEF DESCRIPTION OF THE DRAWINGS

Referring now to the drawings in which like reference numbers represent corresponding parts throughout:

FIG. 1A shows a side view of a conventional microstrip transmission line being fed with a source excitation voltage and terminated with a resistor;

FIG. 1B shows a section view of a conventional microstrip transmission line;

FIG. 2 shows how the effective dielectric constant of a conventional microstrip transmission line (prior art) varies with frequency;

FIG. 3A shows microstrip transmission with a graded index dielectric.

FIG. 3B shows a section view of the microstrip transmission with a graded index dielectric together with a graph of the desired dielectric constant of the material as a function of the distance from the center of the line;

FIG. 4A illustrates how in a conventional microstrip transmission line the electric fields tend to bind themselves closer to the trace as the frequency of the signal increases;

FIG. 4B illustrates how in a graded index microstrip transmission line the electric fields bend away from the microstrip trace as the frequency of the signal increases thus compensating for the field crowding effects around the trace;

FIG. 5A shows a plan view of a printed circuit board with a matrix of graded index dielectric sites which provide random routing of microstrip transmission line structures;

FIG. 5B shows a section view of the microstrip transmission with matrix graded index dielectric sites together with a graph of the desired dielectric constant of the material;

FIG. 5C is a diagram showing a microscrip transmission and a graded dielectric that follows the path of the transmission line; and

FIG. 6 shows a section view of a stepwise graded index structure together with a graph of the desired dielectric constant of the composite structure.

### DETAILED DESCRIPTION OF PREFERRED EMBODIMENTS

In the following description, reference is made to the accompanying drawings which form a part hereof, and which is shown, by way of illustration, several embodiments of the present invention. It is understood that other embodiments may be utilized and structural changes may be made without departing from the scope of the present invention.

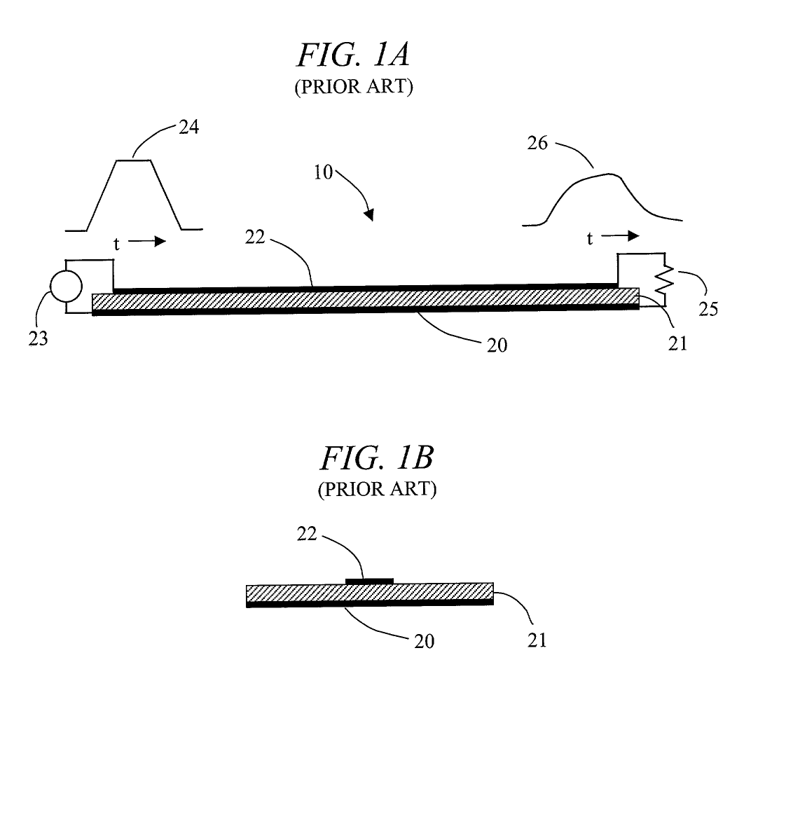

FIG. 1A is a diagram showing a microstrip transmission line structure 10 constructed of a narrow metal foil strip 22 overlaid on a homogenous dielectric material 21 which is in contact with a generally continuous ground plane 20.

FIG. 1B is a diagram showing the proceeding described structure in section view. Typically, such structures are fabricated using conventional printed circuit board techniques which are well know in the art.

Referring back to FIG. 1A, one purpose of a microstrip transmission line structure is to present a predictable characteristic impedance to a signal 23 that is injected into the line and to faithfully transmit that signal 23 to a remote end where it is generally terminated with a suitable termination load such as a resistor 25. However, if the signal 23 has appreciable frequency components (as shown in pulse 24), as the signal 23 propagates down the microstrip transmission line structure, the signal 23 may become distorted, for example, to the shape shown in pulse 26.

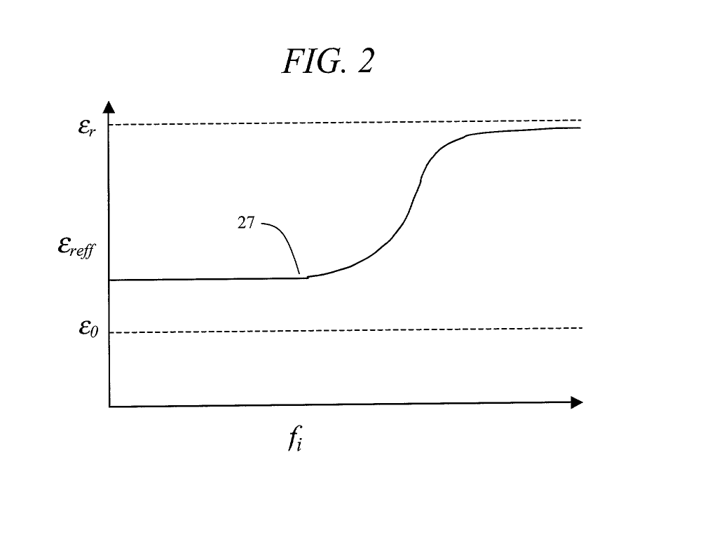

Because a microstrip transmission line structure has inherent dispersive qualities the effective dielectric constant, ε_{reff}, of the dielectric material 21 will exhibit a behavior similar to that shown in FIG. 2. Note that an inflection point 27 occurs at some high frequency where the effective dielectric constant begins to asymptotically approach the dielectric constant of the medium, εᵣ.

This dispersive behavior is different from “anomalous” or normal dispersion in that this is not an intrinsic property of the medium. Rather, this dispersion is a function of the non-homogenous dielectric medium in which the signal is propagating, specifically, the dielectric 21 which supports the transmission line and the air above the structure. In order for the electromagnetic wave to satisfy the boundary conditions at the dielectric-air interface, the phase constant of the signal in the direction of the propagation must lie between the phase constants of the air region and the dielectric region respectively. If this were not so, the signal would not propagate and would either be at or below cut-off for a given wave guide mode.

Referring again to FIG. 2, the effective dielectric constant begins to depart from a flat condition and transitions to the aforementioned point of inflection 27 where the microstrip exhibits the dispersive behavior resulting in signal degradation 26 at the remote end of the microstrip transmission line. This signal degradation can be explained by noting that the velocity of an electric wave is:

$$v = \frac{c}{\sqrt{{ϵ}_{reff}}} ,$$

where c is the velocity of light and ε_{reff} is the effective dielectric constant

Thus, as the effective dielectric constant increases with frequency it slows down the higher frequency components of the signal which cause them to arrive late at the far end of microstrip line and distorting the waveform at that point.

Thus, the objective is to either push this transition out further in frequency or to flatten out the curve over a wider frequency range and, thus, mitigate the dispersive effect.

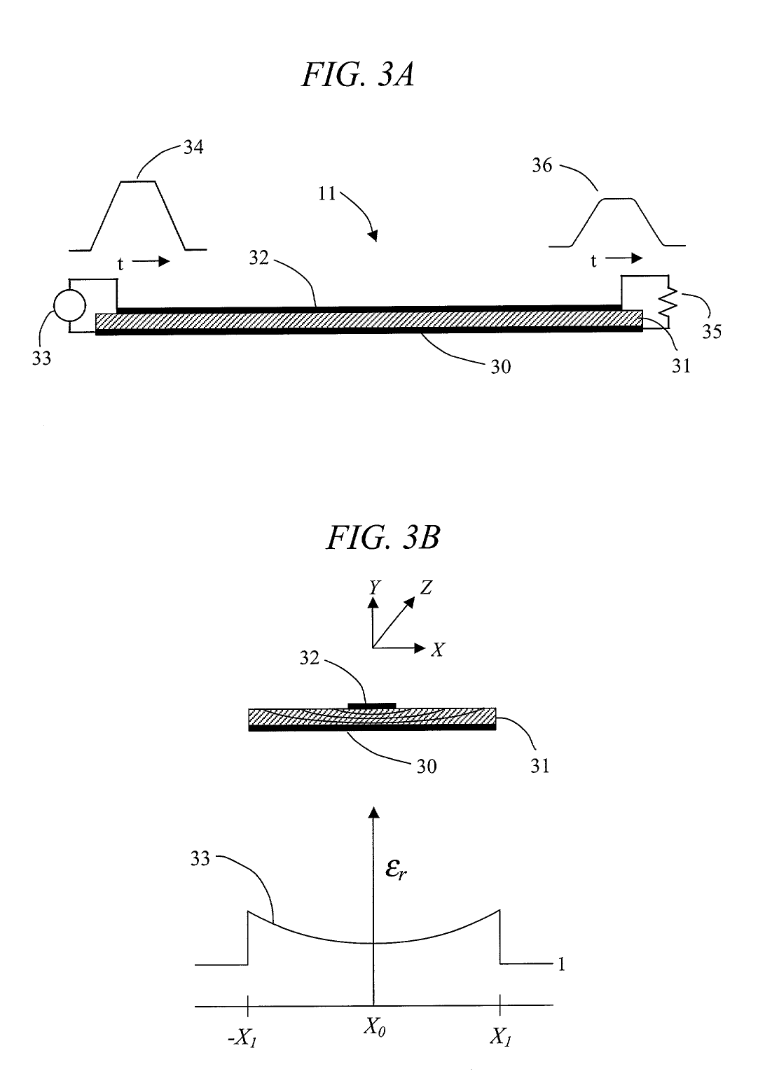

FIG. 3A illustrates a microstrip transmission line structure 11 constructed in a manner similar to that shown in FIG. 1A, except that the narrow metal foil strip 32 is overlaid on a graded index dielectric material 31 which is in contact with a generally continuous ground plane 20.

FIG. 3B is a section view of the structure shown in FIG. 3A. Compared to the structure shown in FIG. 1A, the dielectric constant of the dielectric material 31 is not homogenous as was the case illustrated in FIGS. 1A and 1B. As illustrated by curve 33 the dielectric is graded with the dielectric constant of the material increasing as a distance, X, from the center of the microstrip structure, X₀, out to the edge of the printed circuit structure where the dielectric constant is that of air. In one embodiment, the dielectric is graded in an elliptical fashion such that a slice in the X-Y plane has a dielectric constant generally characterized by the relationship ε≈\sqrt{aX²+bY²}, where a and b are constants.

Since this structure is graded only in the X and Y directions, this structure is only effective for signals propagating down the Z direction. Multiple parallel microstrip transmission paths may be constructed by a repeated pattern in the X direction of FIG. 3B.

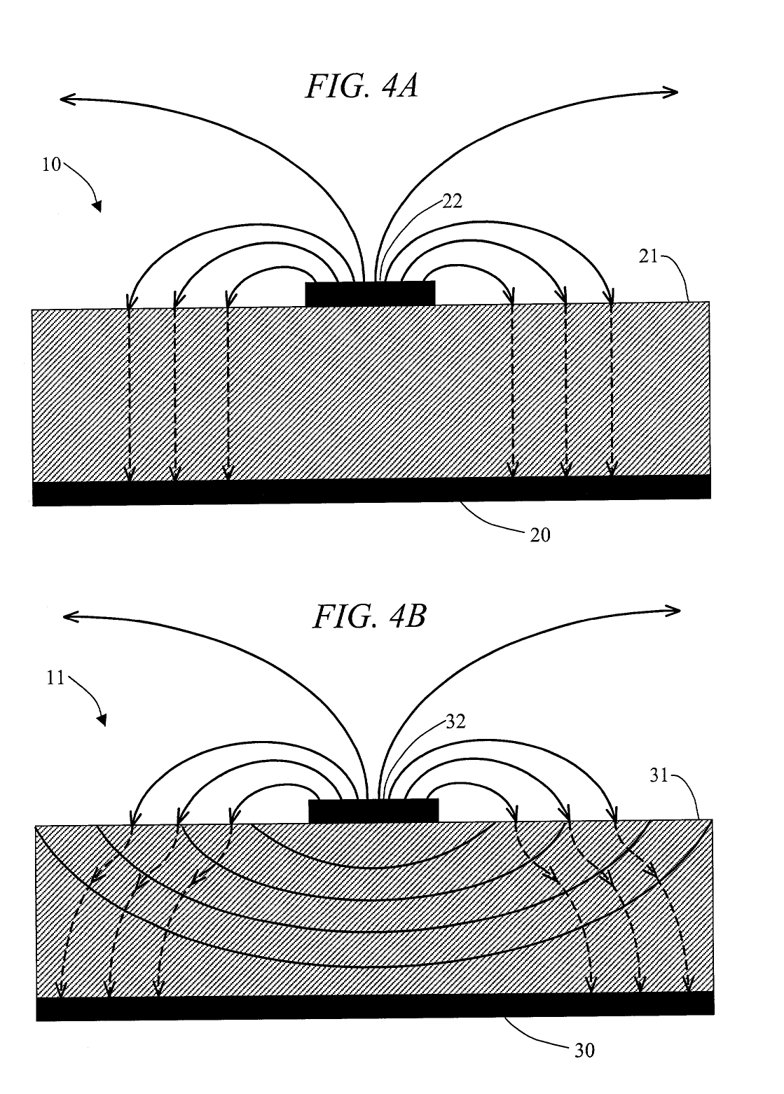

FIGS. 4A and 4B illustrate how the operation of the graded index differs from a conventional microstrip structure. In a conventional microstrip structure 10 with a homogenous dielectric (illustrated in FIG. 4A), as the frequency of the signal increases, the fields tend to bind themselves closer to the trace and within the dielectric itself. As this occurs, the electric fields angle closer towards the center of the structure. However, in the graded index structure, (illustrated in FIG. 4B), the fields are forced to bend towards the direction away from the microstrip trace 32 thus compensating for the field crowding effects around the trace 32 itself. This has the effect of compensating for the dispersive nature of the microstrip 32 and forcing the signal to maintain its shape as it propagates down the transmission path. As an example, if a trapezoidal pulse, 34 in FIG. 3A, is transmitted down a graded microstrip structure 32, the higher frequency components (3^{rd}, 5^{th}, etc. harmonics) will propagate at slightly faster rates that the first harmonic because the electromagnetic waves for the higher frequency components are bound closer to the microstrip 32 where the lowest dielectric constant exists in the structure (see, e.g. FIG. 3A). Thus the overall effect is that of a quasi-TEM (transverse electromagnetic) wave essentially bending backwards as the wavefront propagates down the transmission path resulting in a less distorted signal 36 at the far end of transmission line 11 in FIG. 3A. Note that the signal 26 will still undergo attenuation due to other effects.

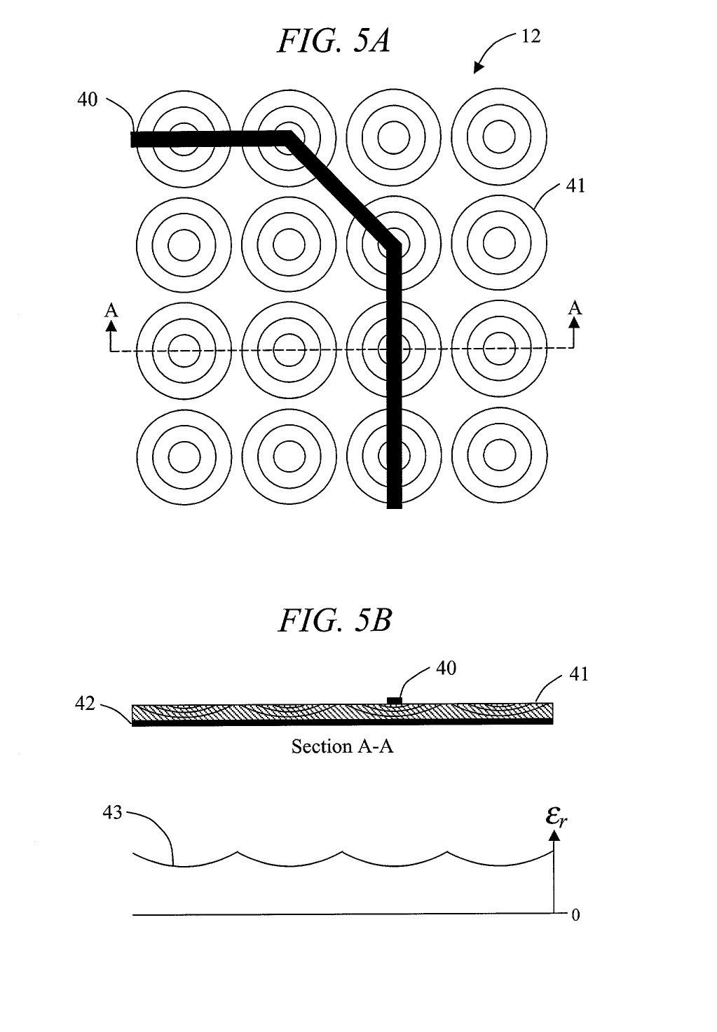

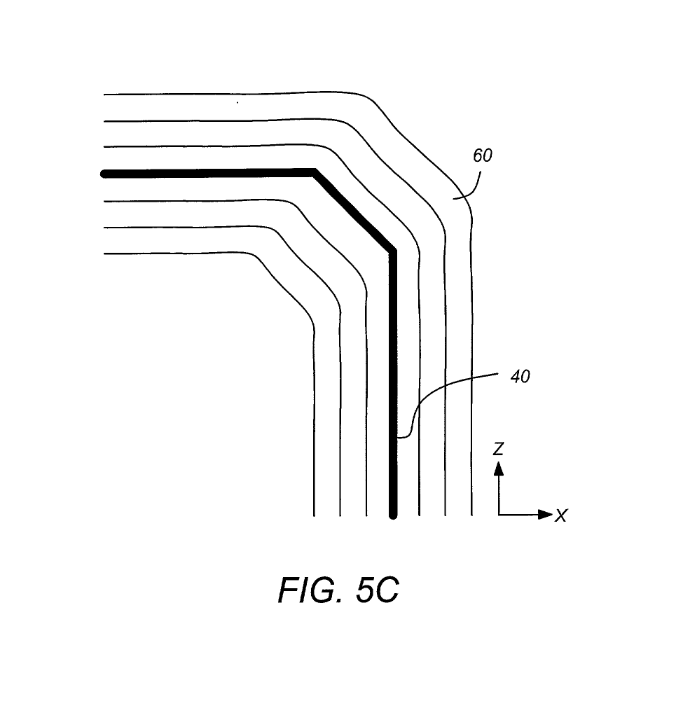

It is more common to propagate signals in a microstrip structure down random paths in the X-Z plane rather than in one direction. FIG. 5A illustrates a plan view 12 of a printed circuit board structure where by a matrix of bowl-shaped graded index dielectric sites 41 are located in the projected path of a microstrip transmission line 40. The sites 41 act upon the microstrip transmission line structure in much the same manner as that described earlier in FIGS. 3B and 4B. Note that microstrip structures must necessarily be aligned with the sites 41 as shown in FIG. 5A in order to effectively compensate for the dispersive nature of the line. Although small portions of the line will not have the full effect of the graded index the average effect will prevail.

FIG. 5B illustrates a section view A-A of the printed circuit board structure 12 shown in FIG. 5A. Microstrip transmission line structure 40 is shown centered over dielectric sites 41 which are located over ground plane 42. Graphical curve 43 illustrates how the relative dielectric constant, εᵣ varies from the center of the dielectric site 41 in a circular manner. It will be recognized that a multiplicity of microstrip structures can be routed on the same planar structure.

FIG. 5C illustrates another embodiment of the invention in which the graded dielectric 60 follows the path of the transmission line itself. In this embodiment, slices of the dielectric in the plane perpendicular to the microstrip 40 all exhibit the same dielectric grade characteristic.

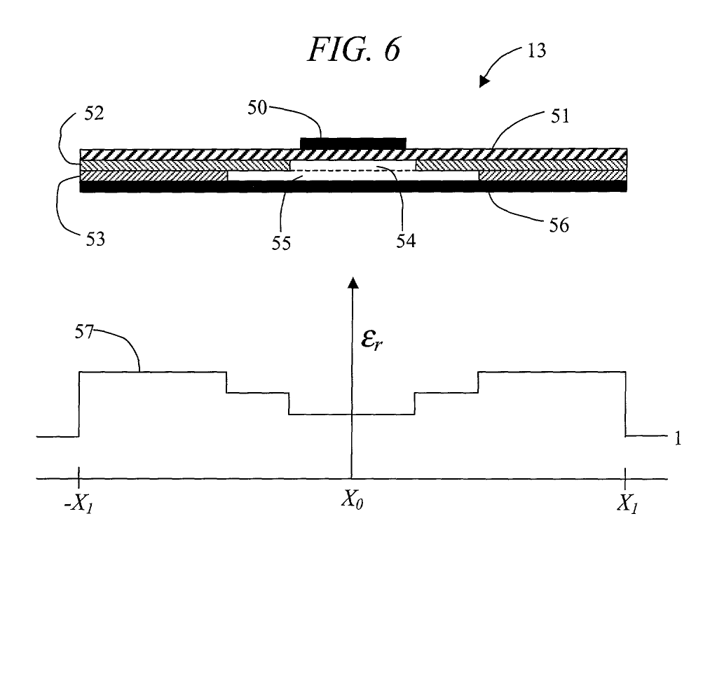

FIG. 6 presents a section view 13 of a step wise graded index structure. This structure is similar to that shown in FIG. 3A, but illustrates a laminated dielectric structure which may be easier to produce than the structure illustrated in FIG. 3A. In the construction of this embodiment of the structure 13, laminate dielectric 53 with a relative dielectric constant εᵣ₅₃ is initially joined to ground plane 56. Dielectric 53 comprises a void 55. This void 55 is preferably air however it may be any material in which the dielectric constant is less than laminate dielectric 53. Next, a second laminate dielectric 52 is joined to laminate dielectric 53 and, possibly, material in void 55 (if such material in the void 55 is utilized). Laminate dielectric 52 preferably has a relative dielectric constant εᵣ₅₃ which is less than εᵣ₅₂. Again, laminate dielectric 52 has void 54 but which is smaller in width than void 55. Void 54 again may be air or any other material in which the relative dielectric constant is less than εᵣ₅₂. Finally, a continuous dielectric laminate 51 is joined to dielectric laminate 52 and, possibly, material in void 54. Dielectric laminate 51 preferably has a dielectric constant εᵣ₅₁ that is less than εᵣ₅₂. Microstrip transmission line 50 is than applied over dielectric 51 in a conventional manner. The continuous characteristic of dielectric 51 assures support of microstrip line 50 in the event voids 54 and 55 are air. Graphical curve 57 illustrates how the effective dielectric constant of the composite structure 13 varies in a step wise manner with the relative dielectric constant, εᵣ, varying from a maximum at the periphery of microstrip 50 to a minimum at the center of microstrip 50. It should be noted that many dielectric structures may be constructed to provide the characteristic of graphical curve 57 and that they need not be exactly as described above. In fact, it is not necessarily the case that structure 13 be contained to three dielectric layers as shown. Similar effects can be obtained with two layers or more than three layers.

Note that structure 13 can be applied to a linear dielectric structure like that shown in FIGS. 3A and 3B. However, it may also be applied to matrix structures as shown in FIGS. 5A and 5B where the geometry of the site may be round or square or other geometrical configurations.

### Conclusion

This concludes the description of the preferred embodiments of the present invention. The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. An apparatus for selectively phase shifting one or more frequency components of a signal, comprising:
a conductor;
a ground plane; and
a dielectric, disposed between the ground plane and the conductor, wherein the dielectric is characterized by a non-homogeneous dielectric constant.

2. The apparatus of claim 1, wherein dielectric constant of the non-homogeneous dielectric decreases as a distance from the dielectric to the conductor increases.

3. The apparatus of claim 2, wherein the conductor is longitudinally disposed along a Z axis of a coordinate system having a Y axis perpendicular to the Z axis, and an X axis perpendicular to the Y and the Z axes.

4. The apparatus of claim 3, wherein the ground plane is disposed a distance from the conductor along the X axis, and wherein the dielectric constant of the dielectric varies with the distance from the conductor in an X-Y plane defined by according to a relationship generally described by ε≈\sqrt{aX²+bY²}, wherein a and b are constants.

5. The apparatus of claim 1, wherein the non-homogeneous dielectric constant is characterized by a first dielectric constant adjacent the conductor and a second dielectric constant higher than the first dielectric constant not adjacent to the conductor.

6. The apparatus of claim 1, wherein the dielectric includes a first dielectric portion adjacent the strip conductor and a second dielectric portion not adjacent the strip conductor, wherein the dielectric constant of the first dielectric portion is different than the dielectric constant of the second portion.

7. The apparatus of claim 4, wherein the dielectric constant of the first dielectric portion is lower than the dielectric constant of the second dielectric portion.

8. The apparatus of claim 1, wherein the conductor is a strip conductor.

9. A method of producing a microstrip, comprising the steps of:
disposing a first dielectric having a dielectric constant ε₁ on a ground plane;
disposing a second dielectric having a second dielectric constant ε₂ lower than the first dielectric constant ε₁ on the first dielectric; and
disposing a third dielectric having a third dielectric constant ε₃ lower than the second dielectric constant ε₂; and
wherein the first dielectric has a first void, the second dielectric has a second void smaller than the first void and disposed over the first void.
